(19) United States
(12) Patent Application Publication
(10) Pub. No.: US 2007/0275532 A1
(43) Pub. Date: Nov. 29, 2007

(54) OPTIMIZED DEEP SOURCE/DRAIN JUNCTIONS WITH THIN POLY GATE IN A FIELD EFFECT TRANSISTOR

(75) Inventors: Dureseti Chidambarrao, Weston, CT (US); Yaocheng Liu, Elmsford, NY (US); Kern Rim, Yorktown Heights, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/420,053

(22) Filed: May 24, 2006

(51) Int. Cl. H01L 21/336

(52) U.S. Cl. 438/300; 257/E29.266; 257/E29.278

(57) ABSTRACT

A semiconductor structure in which the poly depletion and parasitic capacitance problems with poly-Si gate are reduced is provided as well as a method of making the same. The structure includes a thin poly-Si gate and optimized deep source/drain doping. The method changes the sequence of the different implantations steps and makes it possible to fabricate the structure without having dose loss or doping penetration problems. In accordance with the present invention, a sacrificial hard mask capping layer is used to block the high energy implantation and a 3-1 spacer (off-set spacer, first spacer and second spacer) scheme is used to optimize the source/drain doping profile. With this approach, the dose implanted into the thin poly-Si gate can be increased while the deep source/drain implantation can be optimized without worrying about the penetration problem.

### FIELD OF THE INVENTION

The present invention relates to a semiconductor structure and a method of fabricating the same. More particularly, the present invention relates to a complementary metal oxide semiconductor (CMOS) structure including a thin poly gate and optimized deep source/drain regions that are located in a semiconductor substrate at the footprint of the poly gate. The present invention also provides a method of fabricating such a CMOS structure.

### BACKGROUND OF THE INVENTION

Performance gains in high performance logic circuits rely on increasing the ‘on’ current without increasing the ‘off’ current. As device dimensions are scaled, performance gains are more difficult to achieve. One particular aspect of scaling involves reducing the physical thickness of the gate oxide. For a given gate voltage, an electric field is established across the gate oxide. If the gate oxide is reduced, then the magnitude of the electric field increases for the same gate voltage. In the case of a pFET device, a negative voltage is applied to the gate to turn ‘on’ the device. When the device is in the ‘on’ state, the channel becomes inverted with respect to its majority carrier type. As inversion charges in the channel increase, the gate becomes depleted of its majority carrier.

Depletion of charge carriers at, or near, the interface between the gate oxide/polySi gate (known as the poly depletion effect) has been a problem for complementary metal oxide semiconductor (CMOS) devices, and in particular for pFET devices. The depletion causes a virtual increase in gate dielectric thickness thereby adversely impacting device performance. The effect of the depletion becomes increasingly important with progressively decreasing gate oxide thickness because the poly depletion effect increase becomes fractionally higher.

In addition, the capacitance between gate poly and source/drain contact metal also becomes a factor that increase the delay of the integrated circuits. This capacitance increases with poly height.

In the traditional CMOS process, poly-Si gates are doped during the self-aligned source/drain implantation and they are activated during a subsequent activation anneal step. The implantation energy used in the prior art process is selected so that the dopant atoms will not penetrate to deeply within the poly-Si gate electrode. As such, there is a relatively small concentration (on the order of about 10¹⁸ atoms/cm³ or less) of dopant atoms that can reach the gate dielectric/poly-Si gate interface by implantation. Although diffusion can bring more dopant atoms to the gate dielectric/poly-Si interface, the doping concentration at the interface is always the lowest. Moreover, the dopant atoms present at the gate dielectric/poly-Si gate interface are unevenly distributed.

One way to circumvent the above problems is to reduce the thickness (i.e., height) of the poly-Si gate to improve the activated doping concentration at the gate dielectric/poly-Si gate interface and to reduce the capacitance between poly-Si gate and source/drain contact metal. Although it is possible to reduce the thickness of the poly-Si gate, high energy (on the order of about 20 keV or greater for As, 5 keV or greater for B, 10 keV or greater for P) is often needed for implantation of the deep source/drain regions in order to reduce the external resistance for the device. Usually, the deep source/drain implantation is a self-aligned process with the poly-Si gate (and some sidewall spacers) masking the channel region of the device. As a result, the dose implanted into the deep source/drain regions is also implanted into the poly-Si gate. The combination of the thin poly-Si gate and high source/drain implantation energy, however, leads to the problem that some of the dose may penetrate the thin poly-Si and the gate dielectric and enter into the channel region, damaging the device.

Some ideas have been proposed to decouple the thin poly-Si from the deep source/drain implantation. For example, a hard mask capping layer can be used on top of the thin poly-Si so that the high energy implantation can not penetrate the whole stack. One problem with such an approach is that some of the dose will be lost in the capping layer and the doping concentration in the poly-Si, particularly at the interface between the poly-Si gate and the gate dielectric, will be reduced.

In view of the above, there is still a need for providing a better technique that is capable of decoupling the implantation of the thin poly-Si gate region from the deep source/drain regions such that the dose used in forming the deep source/drain regions does not penetrate into the device channel, yet providing a high concentration of dopants with the thin poly-Si gate, especially at the interface between the thin poly-Si gate and the gate dielectric.

### SUMMARY OF THE INVENTION

The present invention provides a method for solving the dose loss problem mentioned above by changing the sequence of the different implantations steps. In accordance with the present invention, a sacrificial hard mask capping layer is used to block the high energy implantation and a 3-1 spacer (off-set spacer, first spacer and second spacer) scheme is used to optimize the source/drain doping profile. A buffer implantation, which is typically performed after the first spacer has been formed, is delayed to after the removal of the second spacer (also referred to herein as a disposal spacer since it is removed from the structure during processing) and the hard mask capping layer. With this approach, the dose implanted into the thin poly-Si gate can be increased while the deep source/drain implantation can be optimized without worrying about the penetration problem. Gate pre-doping prior to the hard mask capping layer formation can also be used to improve the thickness of the gate dielectric at inversion.

In general terms, the method of the present invention comprises:
forming at least one patterned gate stack on a surface of a semiconductor substrate, said at least one patterned gate stack comprising, from bottom to top, a gate dielectric, a poly-Si containing material having a thickness of less than 100 nm, and a hard mask;
forming an off-set spacer, a first spacer and a second spacer abutting the at least one patterned gate stack, wherein after forming said off-set spacer source/drain extension regions are formed and after forming said second spacer deep source/drain regions having a depth, as measured from an upper surface of the semiconductor substrate, of about 20 nm or greater and a dopant concentration of about 10¹⁹ atoms/cm³ or greater are formed;
removing said second spacer and said hard mask, wherein said removing of said hard mask exposes said poly-Si containing material and is performed in a same step as the removing of the second spacer or in another step that follows the removing of the second spacer; and
implanting ions into said exposed poly-Si containing material to provide a dopant concentration of about 10¹⁹ atoms/cm³ or greater into said exposed poly-Si containing material.

The present invention contemplates forming at least one nFET, at least one pFET or a combination of at least one nFET and at least one pFET on the same semiconductor substrate.

When at least one nFET and at least one pFET are formed, the method includes the steps of:
forming at least one patterned gate stack on a surface of a semiconductor substrate in each of an nFET device region and a pFET device region, each patterned gate stack in said device regions comprises, from bottom to top, a gate dielectric, a poly-Si containing material having a thickness of less than 100 nm, and a hard mask;
forming an off-set spacer, a first spacer and a second spacer abutting the at least one patterned gate stack in each device region, wherein after forming said off-set spacer source/drain extension regions are formed and after forming said second spacer deep source/drain regions having a depth, as measured from an upper surface of the semiconductor substrate, of about 20 nm or greater and a dopant concentration of about 10¹⁹ atoms/cm³ or greater are formed;
removing said second spacer and said hard mask from each of said device regions, said hard mask is removed exposing the poly-Si containing material in each device region in a same step as the removing of the second spacer or in another step that follows the removing of the second spacer; and
selectively implanting ions into said exposed poly-Si containing material in each device region to provide a dopant concentration of about 10¹⁹ atoms/cm³ or greater into said exposed poly-Si containing material in each of said device regions.

In addition to the general method described above, the present invention also relates to the semiconductor structure, e.g., CMOS structure, that is formed therefrom. In general terms, the semiconductor structure of the present application includes at least one field effect transistor (FET) located on a semiconductor substrate, said at least one FET including a patterned stack comprising, from bottom to top, a gate dielectric, and a doped poly-Si containing material having a thickness of about 100 nm or less, wherein said doped poly-Si containing material has a concentration of dopants that is about 10¹⁹ atoms/cm³ or greater, and said semiconductor substrate includes deep source/drain regions that have a depth, as measured from an upper surface of the semiconductor substrate, of about 20 nm or greater and a dopant concentration of about 10¹⁹ atoms/cm³ or greater.

### BRIEF DESCRIPTION OF THE DRAWINGS

FIGS. 1A-1F are pictorial representations (through cross section views) depicting the basic processing steps of one embodiment of the present invention.

FIGS. 2A-2F are pictorial representations (through cross sectional views) depicting the basic processing steps of a second embodiment of the present invention.

### DETAILED DESCRIPTION OF THE INVENTION

The present invention, which provides a technique for providing an increased dopant dose to a thin poly-Si gate, while optimizing the dose within the deep source/drain regions as well as the resultant CMOS structure that is formed by the same, will now be described in greater detail by referring to the following discussion and drawings that accompany the present application. It is noted that the drawings of the present application are provided for illustrative purposes and, as such, they are not necessarily drawn to scale.

In the description and drawings that follow, a preferred embodiment of the present invention is described and illustrated in which at least one nFET and at least one pFET are formed onto a surface of a semiconductor substrate. Although such description and illustration are made, the present invention is not limited to forming such a CMOS structure. Instead, the present invention can be used in forming a CMOS structure including at least one pFET or at least one nFET on a surface of the substrate.

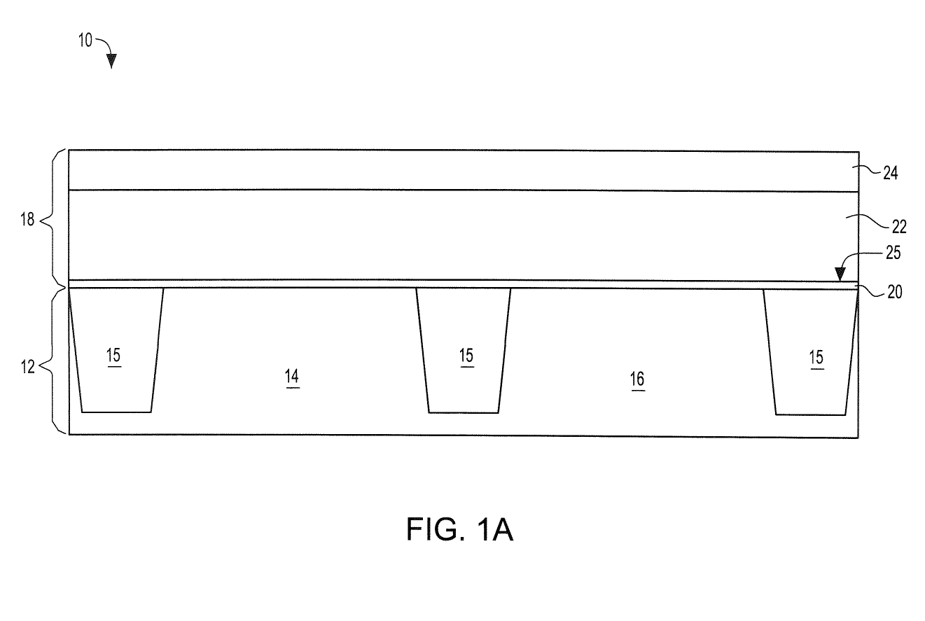

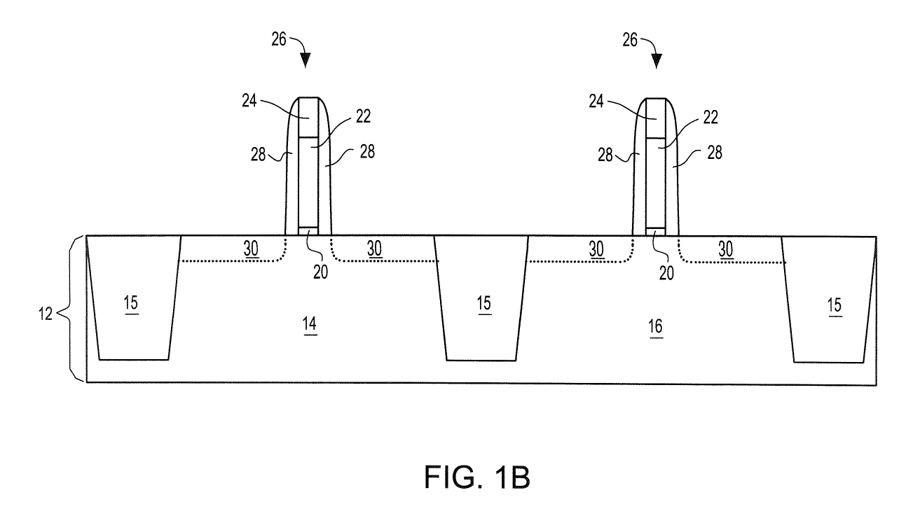

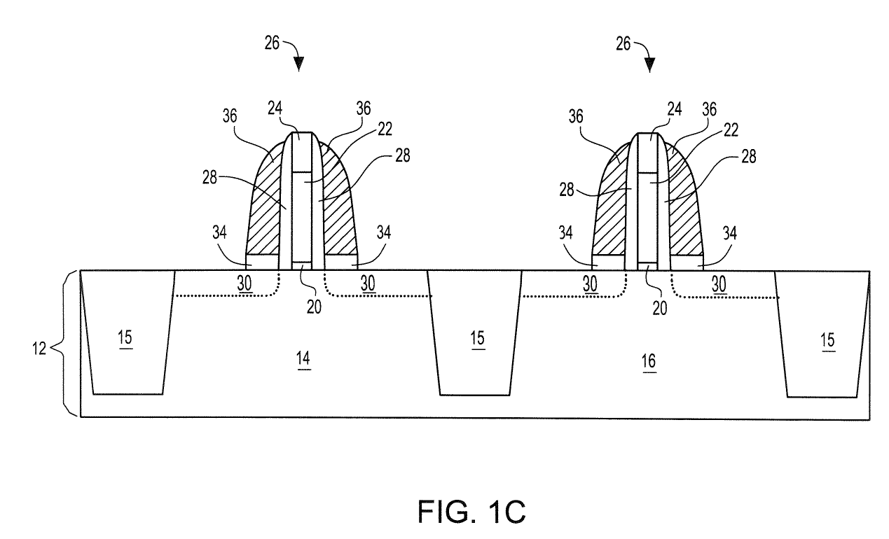

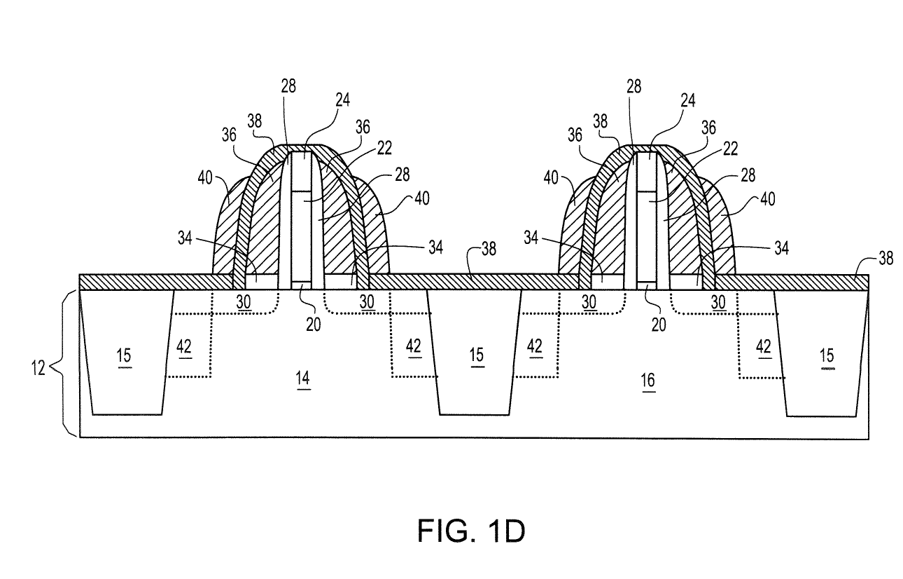

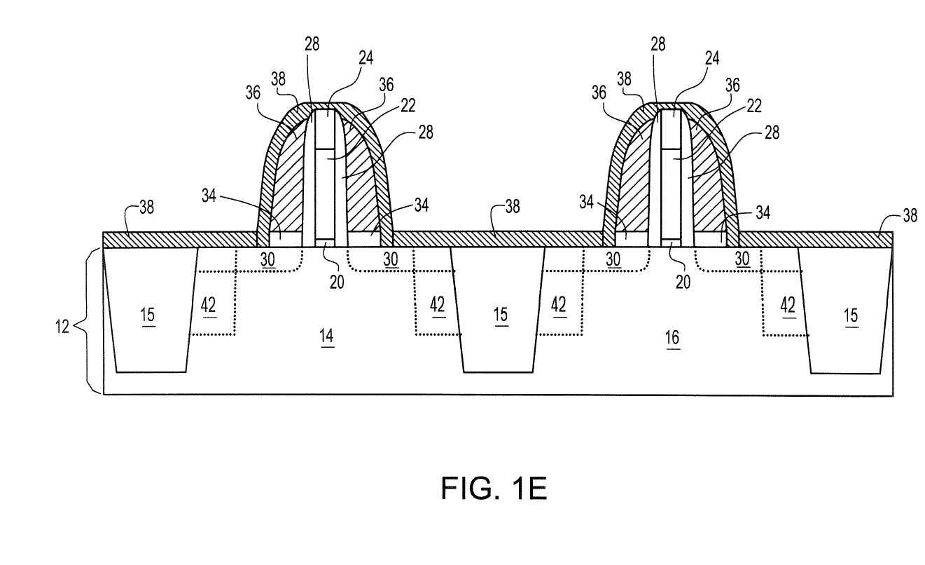

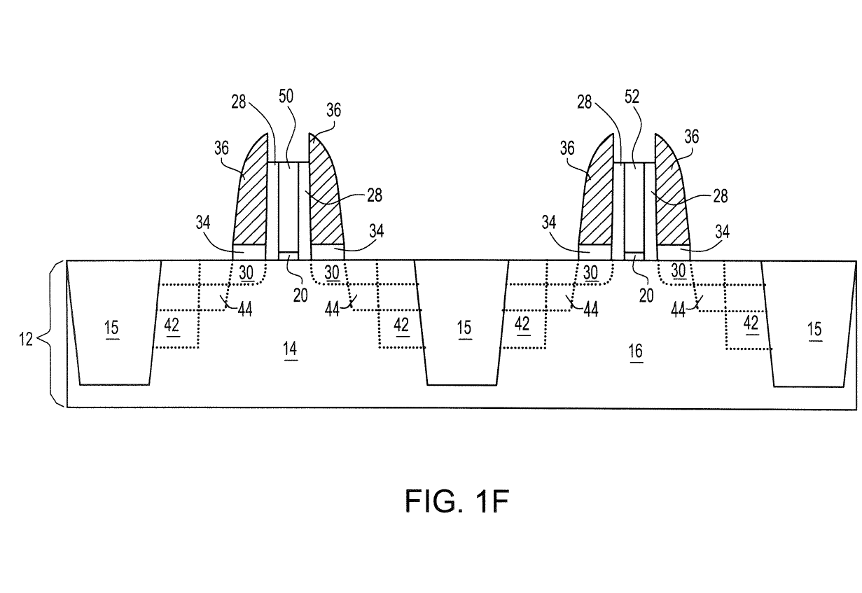

Reference is made to FIGS. 1A-1F which illustrate the basic processing steps of a first embodiment of the present invention that are used in forming a CMOS structure including at least one nFET and at least one pFET wherein an increased dose is provided to the poly-Si gate of each of the FETs, while optimizing the dose provided within the deep source/drain regions. In accordance with the present invention, this is achieved by decoupling the implantation of the poly-Si containing material from that of the deep source/drain regions.

Reference is first made to FIG. 1A which illustrates an initial structure 10 that is employed in the present invention. As is illustrated, the initial structure 10 includes a semiconductor substrate 12 that comprises at least one nFET device region 14 and at least one pFET device region 16. The at least one nFET device region 14 is separated in part from the at least one pFET device region 16 by an isolation region 15. The initial structure 10 also includes a material stack 18 located atop the substrate 12 in both the nFET device region 14 and the pFET device region 16. The material stack 18 includes, from bottom to top, a gate dielectric 20, a poly-Si containing material 22 and an oxide hard mask 24. The oxide hard mask 24 is a sacrificial capping layer which will be removed in subsequent processing steps.

The semiconductor substrate 12 of the initial structure 10 includes any semiconducting material including, for example, Si, SiGe, SiGeC, SiC, Ge alloys, GaAs, InAs, InP and other III/V or II/VI compound semiconductors. In addition to these listed types of semiconducting materials, the present invention also contemplates cases in which the semiconductor substrate 12 is a layered semiconductor such as, for example, Si/SiGe, Si/SiC, silicon-on-insulators (SOIs) or silicon germanium-on-insulators (SGOIs). In some embodiments of the present invention, it is preferred that the semiconductor substrate 12 be composed of a Si-containing semiconductor material, i.e., a semiconductor material that includes silicon. The semiconductor substrate 12 may be doped, undoped or contain doped and undoped regions therein.

It is also noted that the semiconductor substrate 12 may be strained, unstrained or contain strained regions and unstrained regions therein. The semiconductor substrate 12 may also have a single crystal orientation or alternatively, the substrate 12 may be a hybrid semiconductor substrate that has surface regions having different crystallographic orientations. For example, the semiconductor substrate 12 within the nFET device region 14 may have a surface crystal orientation that is (100), while the semiconductor substrate within the pFET device region 16 may have a surface crystal orientation that is (110). The hybrid substrates may have bulk characteristics, SOI like characteristics or combinations of both bulk and SOI like characteristics.

The semiconductor substrate 12 may also have one or more isolation regions 15 such as, for example, trench isolation regions or field oxide isolation regions, located therein. The one or more isolation regions, which are typically present between the nFET device region and pFET device region, are formed utilizing conventional processing which is well known to those skilled in the art of semiconductor device manufacturing.

The gate dielectric 20 of the material stack 18 is formed on the surface of the semiconductor substrate 12 after the substrate has been processed. The gate dielectric 20 can be formed by a thermal growing process such as, for example, oxidation. Alternatively, the gate dielectric 20 can be formed by a deposition process such as, for example, chemical vapor deposition (CVD), plasma-assisted CVD, atomic layer or pulsed deposition (ALD or ALPD), evaporation, reactive sputtering, chemical solution deposition or other like deposition processes. The gate dielectric 20 may also be formed utilizing any combination of the above processes.

The gate dielectric 20 is comprised of an insulating material (or material stack) having a dielectric constant of about 4.0 or greater, preferably greater than 7.0. The dielectric constants mentioned herein are relative to a vacuum, unless otherwise stated. Note that SiO₂ typically has a dielectric constant that is about 4.0. Specifically, the gate dielectric 20 employed in the present invention includes, but is not limited to: an oxide, nitride, oxynitride and/or silicates including metal silicates, aluminates, titanates and nitrides. In one embodiment, it is preferred that the gate dielectric 20 is comprised of an oxide such as, for example, SiO₂, HfO₂, ZrO₂, Al₂O₃, TiO₂, La₂O₃, SrTiO₃, LaAlO₃, Y₂O₃ and mixtures thereof Of these oxides, SiO₂ is typically used as the gate dielectric material.

The physical thickness of the gate dielectric 20 may vary, but typically, the gate dielectric 20 has a thickness from about 0.5 to about 10 nm, with a thickness from about 0.5 to about 5 nm being more typical.

After forming the gate dielectric 20, a poly-Si containing material 22 is formed on the gate dielectric 20 utilizing a known deposition process such as, for example, physical vapor deposition (PVD), CVD or evaporation. As shown in FIG. 1A, the poly-Si containing material 22 forms an interface 25 with the underlying gate dielectric 20.

The poly-Si containing material 22 comprises polycrystalline Si, polycrystalline SiGe or multilayers thereof. Of these materials, it is preferred that the poly-Si containing material to be comprised of polycrystalline Si. In some embodiments, the poly-Si containing material 22 is undoped at this point of the present invention. In other embodiments of the present invention, the poly-Si containing material 22 is doped at this point of the present invention. Pre-doping may be achieved utilizing an in-situ doping deposition process, or deposition followed by gas phase doping, or ion implantation. Typically, the poly-Si containing material 22 used is a thin film having a vertical thickness that is about 100 nm or less, with a thickness from about 10 to about 50 nm being more typical.

The material stack 18 shown in FIG. 1A also includes an oxide hard mask 24 which is formed atop the first poly-Si containing material 22. The hard mask 24 can be formed utilizing a thermal process such as, for example, oxidation. Alternatively, a deposition process such as, for example, CVD, PECVD, PVD, atomic layer deposition, evaporation or chemical solution deposition, can be used in forming the oxide hard mask 24. Combinations of the aforementioned techniques are also contemplated for forming the oxide hard mask 24. Typically, the oxide hard mask 24 is comprised of a low temperature oxide (LTO).

The thickness of the oxide hard mask 24 may vary depending on, for example, the technique used in forming that material layer. Typically, the oxide hard mask 24 of the material stack 18 has a thickness from about 10 to about 1000 nm, with a thickness from about 50 to about 100 nm being even more typical.

After providing the initial structure 10 shown in FIG. 1A, the material stack 18 is patterned to form a patterned gate stack 26 within each of the device regions. In accordance with the present invention, each of the patterned gate stacks formed in the various device regions at this point of the present invention comprising, from bottom to top, the gate dielectric 20, the poly-Si containing material 22, and the oxide hard mask 24.

The patterned gate stacks 26 which are shown, for example, in FIG. 1B are formed by lithography and etching. The lithographic process includes applying a photoresist material (not shown) to the oxide hard mask 24, exposing the photoresist material to a pattern of radiation, and developing the exposed resist utilizing a conventional resist developer. Etching of the patterned stacks 26 is typically performed utilizing a dry etching process such as reactive ion etching, ion beam etching, or plasma etching. Alternatively, a chemical wet etching process can be used to etch each of the gate stacks 26. In addition to these specified etching techniques, the present invention also contemplates utilizing any combination thereof.

Each of the patterned gate stacks 26 can also be passivated at this point of the present invention by subjecting the same to a thermal oxidation, nitridation or oxynitridation process. The passivation step forms a thin layer of passivating material (not shown) about the material stack. This step may be used instead or in conjunction with the subsequent step of spacer formation. When used with the spacer formation step, spacer formation occurs after the material stack passivation process.

After forming the patterned gate stacks 26 within each device region, an off-set spacer 28 is formed on exposed sidewalls thereof. The resultant structure including the off-set spacer 28 is also shown in FIG. 1B. The off-set spacer 28 is comprised of an insulator such as an oxide, nitride, oxynitride and/or any combination thereof, with oxides being highly preferred. The off-set spacer 28 is formed by deposition and etching. The width of the off-set spacer 28, as measured at a bottom portion thereof, is from about 0 to about 30 nm.

Source/drain extension regions 30 and optionally halo implant regions (not specifically shown) are then formed into the substrate 12 at this point of the present invention. Block masks are typically formed on one of the device region during the ion implantation step, removed and then formed on the structure protecting the other device region that received the previous ion implantation. The source/drain extension regions 30 are formed utilizing ion implantation and an annealing step; the anneal step may be delayed and performed after other implantation steps of the present invention. The annealing step serves to activate the dopants that were implanted by the previous implant step. The conditions for the ion implantation and annealing are well known to those skilled in the art. The source/drain extensions regions 30 are formed prior to the deep source/drain (S/D) implantation using a conventional extension implant. The source/drain extension regions 30 have a doping concentration (n- or p-type) of about 10¹⁹ atoms/cm³ or greater, with a doping concentration of about 10²⁰ atoms/cm³ or higher being more highly preferred. The S/D extension regions 30 are shallower in comparison with the deep source/drain regions to be subsequently formed. The depth of the S/D extension regions is determined in part by the energy of the extension ion implantation. Typically, the extension ion implantation is performed at an energy of about 0.1 to about 10 keV for As or P, about 0.1 to 30 keV for Sb, about 0.1 to about 5 keV for B or BF₂, which provides an extension junction depth of about 1 to about 20 nm below the upper surface of the semiconductor substrate 12. FIG. 1B also shows the presence of the source/drain extension regions 30 at the footprint of each of the patterned gate region 26. As shown, one junction edge of the source/drain extension region is aligned with the outer edge of the off-set spacer 28, while the other junction edge is aligned to the sidewalls of the isolation region 15.

FIG. 1C shows the structure of FIG. 1B after forming a first spacer 36 atop a patterned oxide layer 34. The first spacer 36 and the patterned oxide layer 34 abut and adjoin the off-set spacer 28 in the manner illustrated in FIG. 1C.

The structure shown in FIG. 1C is formed by first providing an oxide layer, such as a LTO, to the structure shown in FIG. 1B. The oxide layer will be subsequently patterned by wet etching to form the patterned oxide which serves as a pedestal for the first spacer 36 to be subsequently formed. Any deposition process including, for example, CVD, PECVD, or PVD can be used in forming the oxide layer. The oxide layer has an as-deposited thickness of about 1 to about 30 nm, with an as-deposited thickness of about 2 to about 20 nm being more highly preferred.

After forming the oxide layer, the first spacer 36 is formed by deposition and etching. Specifically, the first spacer 36 is a wide spacer that is comprised of a nitride, oxynitride and/or any combination thereof. The width of the first spacer 36 must be sufficiently wide such that the source and drain silicide contacts (to be subsequently formed) do not encroach underneath the edges of the patterned gate stack. Typically, the source/drain silicide does not encroach underneath the edges of the patterned gate stack when the first spacer 36 has a width, as measured at the bottom, from about 20 to about 80 nm.

It is noted that no implantations occur immediately after the first spacer 36 formation or the formation of the patterned oxide layer 34.

FIG. 1D shows the structure of FIG. 1C after forming a second (disposable) spacer 40 atop an unpatterned oxide layer 38 and subsequent formation of deep source/drain region 42. The second spacer 40 and the unpatterned oxide layer 38 abut and adjoin the first spacer 36 and the patterned oxide layer 34 in the manner illustrated in FIG. 1D.

The structure shown in FIG. 1D is formed by first providing an oxide layer 38, such as a LTO, to the structure shown in FIG. 1C. Any deposition process including, for example, CVD, PECVD, or PVD can be used in forming the oxide layer. The oxide layer 38 has an as-deposited thickness of about 1 to about 30 nm, with an as-deposited thickness of about 2 to about 20 nm being more highly preferred.

After forming the oxide layer 38, the second spacer 40 is formed by deposition and etching. Specifically, the second spacer 40 is a disposable wide spacer that is comprised of a nitride, oxynitride and/or any combination thereof. The width of the second spacer 40, as measured at the bottom, is from about 20 to about 80 nm.

With the 3-1 spacer scheme in place, deep source/drain regions 42 are formed into the substrate 12 by ion implantation and annealing. The annealing, which may be delayed until after subsequent ion implantation processes, serves to activate the dopants implanted into the substrate 12. The conditions for the ion implantation and annealing are well known to those skilled in the art. Block masks are typically formed on one of the device region during the ion implantation step, removed and then formed on the structure protecting the other device region that received the previous ion implantation. The deep source/drain regions 42 have a doping concentration (n- or p-type) of about 10¹⁹ atoms/cm³ or greater, with a doping concentration of about 10²⁰ atoms/cm³ being more highly preferred. The deep source/drain regions 42 are deeper in comparison with the source/drain extension regions 30 previously formed. The depth of the deep source/drain regions 42 are determined in part by the energy of the ion implantation used. Typically, the deep source/drain ion implantation is performed at an energy of about 20 keV or greater for As, 10 keV or greater for P, 30 keV or greater for Sb, 5 keV or greater for B, 8 keV or greater for BF₂, which provides a junction depth below the upper surface of the semiconductor substrate 12 of about 20 nm or greater, preferably 40 nm or greater, and more preferably 50 nm or greater. FIG. 1D also shows the presence of the deep source/drain regions 42 at the footprint of each of the patterned gate regions. As shown, one junction edge of the deep source/drain region 42 is aligned with the outer edge of the second spacer 40, while the other junction edge is aligned to the sidewalls of the isolation region 15.

FIG. 1E illustrates the structure of FIG. 1D after the second (disposable) spacer 40 has been removed therefrom. The second spacer 40 is removed utilizing an etching process that is selective in removing nitride and/or an oxynitride material from the structure. For example, hot phosphoric acid can be used to remove the second spacer 40 from the structure.

At this point of the present invention, the oxide layer 38 as well as the oxide hard mask 24 are removed from the structure utilizing an etching process that selectively removes oxide. For example, HF can be used in removing oxide layer 38 and the oxide hard mask 24 from the structure.

A buffer implant can now be performed which bridges the source/drain extension region 30 to the deep source/drain regions 42. The buffer implant is optional. Although such an implant is optional, it is preferred to utilizing the same in order to provide the aforementioned bridge between the source/drain extension regions 30 and the deep source/drain regions 42. The buffer implant region is denoted by reference numeral 44 in FIG. 1F. The buffer implant region 44 is formed by ion implantation utilizing an energy from about 5 to about 20 keV for As, 5 to about 20 keV for BF₂, 1 to about 5 keV for B, 10 to about 30 keV for Sb, 2 to about 10 keV for P and a dose sufficient to provide a dopant concentration from about 10¹⁹ to about 10²¹ atoms/cm³ is employed. An activation anneal may follow the ion implantation step. Block masks are typically formed on one of the device region during the ion implantation step, removed and then formed on the structure protecting the other device region that received the previous ion implantation. It is noted that the buffer region 44, the deep source/drain region 42 and the source/drain extension region 30 within a specific device region have the same conductivity type.

At this point of the present invention, selective ion implantation is performed which introduces dopant atoms into the exposed poly-Si material containing 22 in each of the device regions. Specifically, n-type dopants are introduced into the exposed poly-Si containing material 22 in the n-device region 14, while p-type dopants are introduced in the exposed poly-Si containing material 22 in the p-device region 16. The order of the implantations is not critical to the present invention. A block mask is used in this process to protect the exposed poly-Si containing material 22 in one device region, while ion implanting into the exposed poly-Si containing material 22 in the other device region. The block mask is removed, another block mask is formed protecting the previous ion implanted device region, and a second ion implantation is performed into the previously protected poly-Si containing material 22.

In the case of the n-device region 14, n-type dopants including at least one atom from Group VA of the Periodic Table of Elements (CAS version) are introduced into the exposed poly-Si containing material 22 utilizing an ion implantation process and annealing. The n-type dopants include for example P, As, Sb or mixtures thereof. The conditions for the ion implantation include a dose that is sufficient to provide the exposed poly-Si containing material 22 within the nFET device region 14 to have a dopant concentration of about 10¹⁹ atoms/cm³ or greater. This dopant concentration is also present at the interface between the gate dielectric 20 and the doped poly-Si containing material. More typically, a concentration of dopants of from about 10²⁰ atoms/cm³ or greater is introduced at this step of the present invention.

In the case of the p-type device region 16, p-type dopants employed in the present invention include at least one atom from Group IIIA of the Periodic Table of Elements (CAS version) and they are introduced into the exposed poly-Si containing material 22 in the pFET device region 16 by ion implantation and annealing. The conditions for the ion implantation include a dose that is sufficient to provide the exposed poly-Si containing material 22 within the pFET device region 16 to have a dopant concentration of about 10¹⁹ atoms/cm³ or greater. This dopant concentration is also present at doped poly-Si containing material/gate dielectric interface. More typically, a concentration of dopants of from about 10²⁰ atoms/cm³ or greater is introduced at this step of the present invention.

In FIG. 1F, reference numeral 50 denotes the n-doped poly-Si containing material within the nFET device region 14, while reference numeral 52 denotes the p-doped poly-Si containing material within the pFET device region 16.

In accordance with the present invention, this anneal includes heating the structure to a temperature of about 650° C. or greater, with a temperature of about 800° C. or greater being more preferred. This anneal is carried out using a furnace anneal, a rapid thermal anneal, a spike anneal or a laser anneal. The exact duration of the anneal varies depending on the thickness of the poly-Si containing material 22 as well as the type of annealing process employed. An inert gas such as He, Ar or He—Ar can be used during the activation annealing process.

Further CMOS processing such as formation of silicided contacts (source/drain and gate) as well as formation of BEOL (back-end-of-the-line) interconnect levels with metal interconnects can be formed utilizing processing steps that are well known to those skilled in the art.

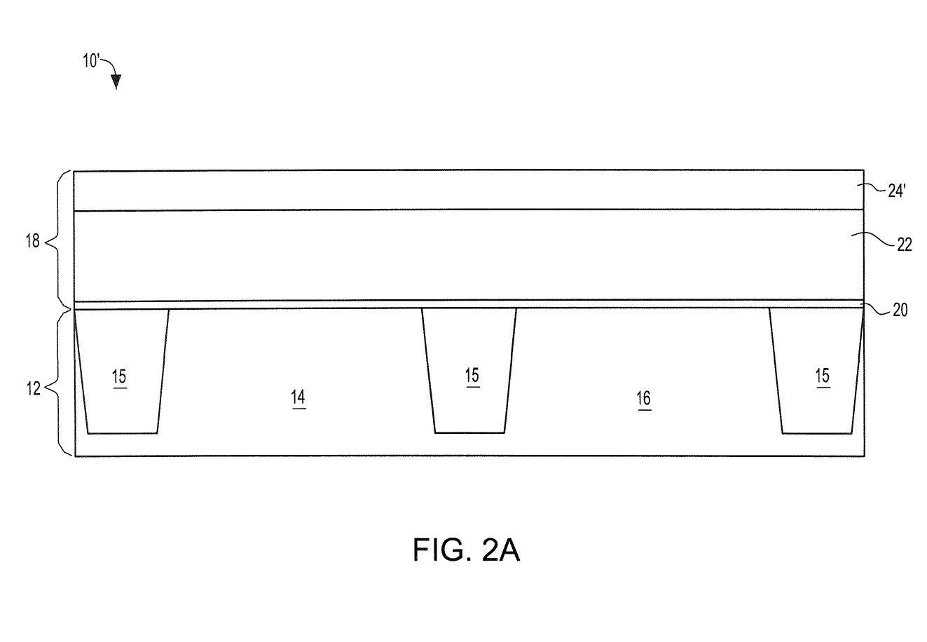

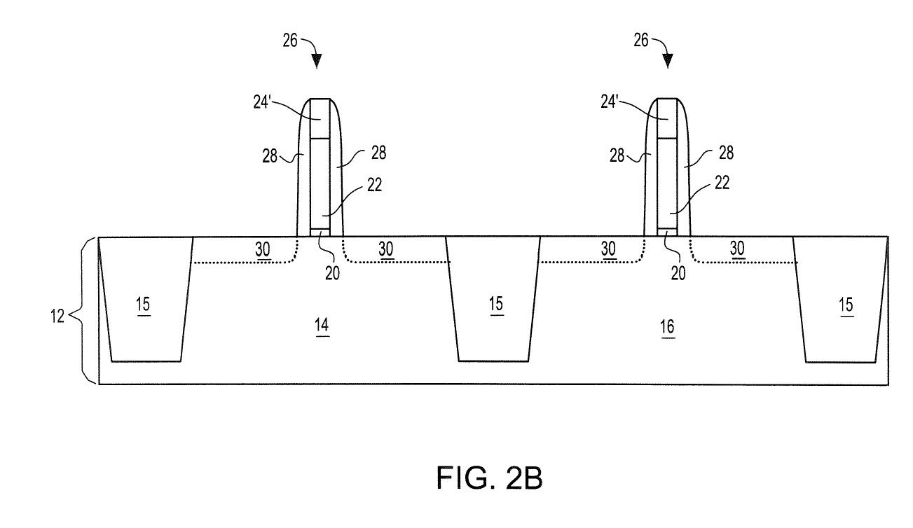

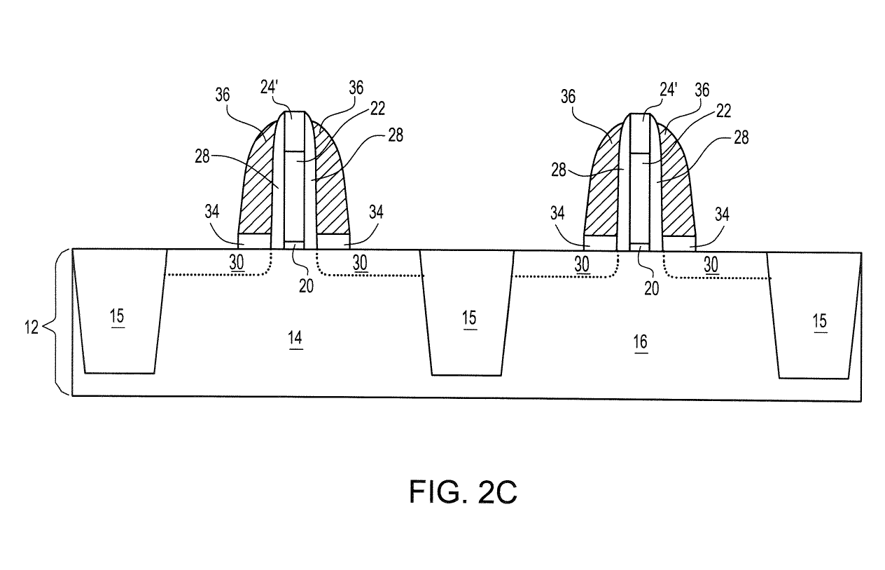

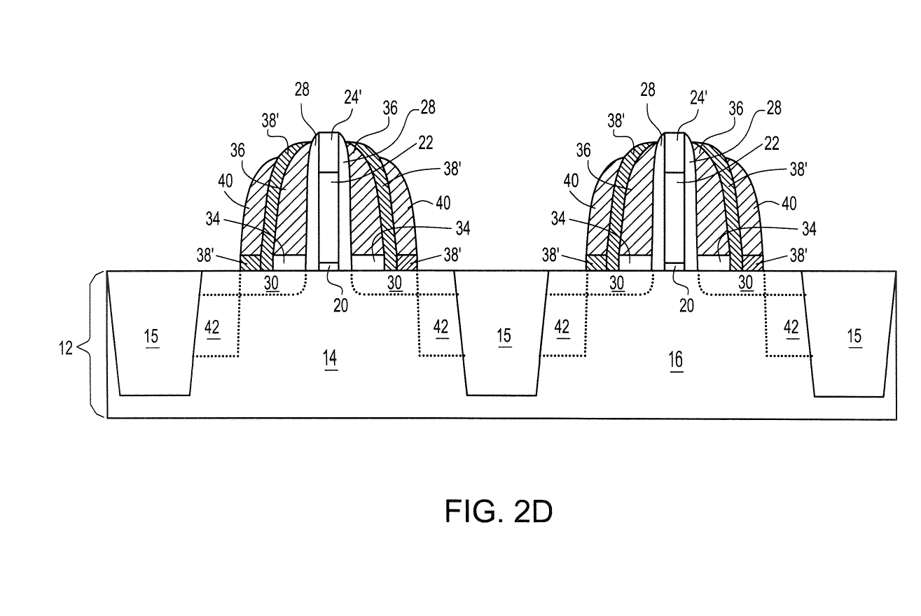

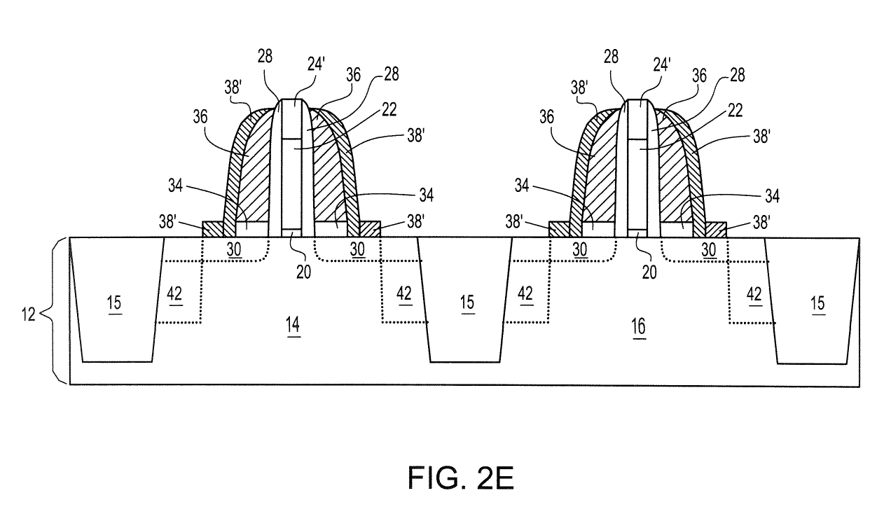

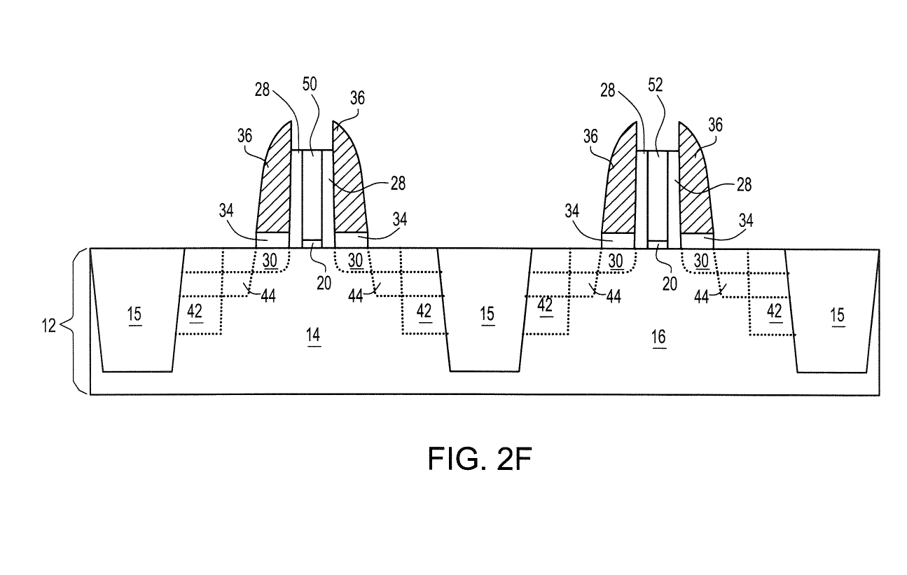

Reference is now made to FIGS. 2A-2F which illustrate a second embodiment of the present invention. The second embodiment of the present invention is similar to the first embodiment with the exception being the composition of the hard mask material. The second embodiment begins by providing the initial structure 10′ shown in FIG. 2A. The initial structure 10′ is the same as that shown in FIG. 1A except that a nitride hard mask 24′ is used instead of the oxide hard mask 24. The nitride hard mask 24′ is formed by a conventional deposition process including those mentioned above in forming the oxide hard mask 24. The nitride hard mask 24′ may also be formed by a nitridation process. The nitride hard mask 24′ has the same thickness range as that of the oxide hard mask 24.

FIG. 2B shows the structure after formation of patterned gate stacks 26 within each of the device regions, formation of an off-set spacer 28 and formation of source/drain extension regions 30. The elements shown in FIG. 2B are comprised of the same basic materials and are made utilizing the techniques that were described for those elements in the first embodiment which were illustrated in FIG. 1B.

FIG. 2C shows the structure after first spacer 36 and patterned oxide layer 34 formation. The elements shown in FIG. 2C are comprised of the same basic materials and are made utilizing the techniques that were described for those elements in the first embodiment which were illustrated in FIG. 1C.

FIG. 2D shows the structure after the second spacer 40 and a second patterned oxide layer 38′ are formed. The structure also includes deep source/drain regions 42. The elements shown in FIG. 2D are comprised of the same basic materials that were described for those elements in the first embodiment which were illustrated in FIG. 1D. The same basic processing steps are used except that the oxide layer 38 is anisotropically etched after the second spacer 40 has been formed forming the second patterned oxide layer 38′. The anisotropic etch removes the oxide layer from atop the nitride hard mask 24′ as well as part of the substrate 12.

FIG. 2E shows the structure after the second spacer 40 has been removed utilizing a etching process that selectively removes nitride as compared to oxide. During this etching step, the nitride hard mask 24′ is also removed exposing the poly-Si containing material of each patterned gate region 26.

FIG. 3F shows the structure after performing an oxide etch that removes the remaining second patterned oxide 38′ from the structure, after performing a buffer implant (forming buffer region 44) and after doping the exposed poly-Si containing material within each device region. The oxide etch is performed utilizing an etching process that selective removes oxide as compared to nitride and/or poly-Si. Note that during the etch, the opening above the exposed poly-Si containing material is enlarged from that shown in FIG. 3E. The buffer implant and the doping of the exposed poly-Si containing material is as described above for the first embodiment of the present invention.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A method of fabricating a semiconductor structure comprising:
forming at least one patterned gate stack on a surface of a semiconductor substrate, said at least one patterned gate stack comprising, from bottom to top, a gate dielectric, a poly-Si containing material having a thickness of less than 100 nm, and a hard mask;
forming an off-set spacer, a first spacer and a second spacer abutting the at least one patterned gate stack, wherein after forming said off-set spacer source/drain extension regions are formed and after forming said second spacer deep source/drain regions having a depth, as measured from an upper surface of the semiconductor substrate, of about 20 nm or greater and a dopant concentration of about 10¹⁹ atoms/cm³ or greater are formed;
removing said second spacer and said hard mask, wherein said removing of said hard mask exposes said poly-Si containing material and is performed in a same step as the removing of the second spacer or in another step that follows the removing of the second spacer; and
implanting ions into said exposed poly-Si containing material to provide a dopant concentration of about 10¹⁹ atoms/cm³ or greater into said exposed poly-Si containing material.

2. The method of claim 1 wherein said hard mask is an oxide hard mask.

3. The method of claim 2 wherein said oxide hard mask is removed in another step that followings the removing of the second spacer.

4. The method of claim 1 wherein said hard mask is a nitride hard mask.

5. The method of claim 4 wherein said nitride hard mask is removed at the same time as the second spacer.

6. The method of claim 1 further comprising forming a buffer implant region in said semiconductor substrate which bridges said source/drain extension regions to said deep source/drain regions.

7. The method of claim 1 wherein said at least one patterned gate stack includes at least one patterned gate stack in an nFET device region and at least one patterned gate stack in a pFET device, said device regions are separated in part by an isolation region that is located within said semiconductor substrate.

8. The method of claim 7 wherein said at least one patterned gate stack in said nFET device region includes n-type ions after said implanting of ions, and said at least one patterned gate stack in said pFET device region includes p-type ions after said implanting of ions, said implanting of ions comprises a selective ion implantation process that utilizes block masks.

9. The method of claim 1 wherein said poly-Si containing material comprises poly-Si.

10. A method of forming a semiconductor structure comprising:
forming at least one patterned gate stack on a surface of a semiconductor substrate in each of an nFET device region and a pFET device region, each patterned gate stack in said device regions comprises, from bottom to top, a gate dielectric, a poly-Si containing material having a thickness of less than 100 nm, and a hard mask;
forming an off-set spacer, a first spacer and a second spacer abutting the at least one patterned gate stack in each device region, wherein after forming said off-set spacer source/drain extension regions are formed and after forming said second spacer deep source/drain regions having a depth, as measured from an upper surface of the semiconductor substrate, of about 20 nm or greater and a dopant concentration of about 10¹⁹ atoms/cm³ or greater are formed;
removing said second spacer and said hard mask from each of said device regions, said hard mask is removed exposing the poly-Si containing material in each device region in a same step as the removing of the second spacer or in another step that follows the removing of the second spacer; and
selectively implanting ions into said exposed poly-Si containing material in each device region to provide a dopant concentration of about 10¹⁹ atoms/cm³ or greater into said exposed poly-Si containing material in each of said device regions.

11. A semiconductor structure comprising:
at least one field effect transistor (FET) located on a semiconductor substrate, said at least one FET including a patterned stack comprising, from bottom to top, a gate dielectric, and a doped poly-Si containing material having a thickness of about 100 nm or less, wherein said doped poly-Si containing material has a concentration of dopants that is about 10¹⁹ atoms/cm³ or greater, and said semiconductor substrate includes deep source/drain regions that have a depth, as measured from an upper surface of the semiconductor substrate, of about 20 nm or greater and a dopant concentration of about 10¹⁹ atoms/cm³ or greater.

12. The semiconductor structure of claim 11 wherein said doped poly-Si containing material comprises polycrystalline Si, polycrystalline SiGe or multilayers thereof.

13. The semiconductor structure of claim 11 wherein said semiconductor substrate is a hybrid substrate having different crystallographic orientations, wherein the crystallographic orientation in a first device region has a (100) crystal orientation, and the crystallographic orientation in a second, different device region has a (110).

14. The semiconductor structure of claim 11 wherein said at least one FET includes at least one nFET and at least one pFET that are separated in part by an isolation region.

15. The semiconductor structure of claim 11 further comprising an off-set spacer located on sidewalls of each FET and a first spacer located on a patterned oxide layer abutting and adjoining said off-set spacer.

16. The semiconductor structure of claim 11 further comprising a source/drain extension region located within said semiconductor substrate.

17. The semiconductor structure of claim 16 further comprising a buffer implant region located with said semiconductor substrate, said buffer implant region providing a bridge between said source/drain extension region and said deep source/drain region.

18. The semiconductor structure of claim 11 wherein said semiconductor substrate is bulk or a semiconductor-on-insulator.

19. The semiconductor structure of claim 11 wherein said gate dielectric is an insulator having a dielectric constant of about 4.0 or greater.

20. The semiconductor structure of claim 11 wherein said doped poly-Si containing material has a dopant concentration of about 10²⁰ or greater atoms/cm³.
